(19) United States
(12) Patent Application Publication
(10) Pub. No.: US 2025/0285686 A1
(43) Pub. Date: Sep. 11, 2025

(54) SOFT-BIT READ FOR SUPER CELLS IN A MEMORY DEVICE

(71) Applicant: Micron Technology, Inc., Boise, ID (US)

(72) Inventor: Tomoharu Tanaka, Yokohama (JP)

(21) Appl. No.: 19/067,373

(22) Filed: Feb. 28, 2025

Related U.S. Application Data
(60) Provisional application No. 63/561,623, filed on Mar. 5, 2024.

(51) Int. Cl. G11C 16/26; G11C 16/08; G11C 29/52

(52) U.S. Cl. CPC G11C 16/26; G11C 16/08; G11C 29/52

(57) ABSTRACT

Control logic in a memory device comprising a plurality of memory cells, wherein respective pairs of the memory cells are grouped into super cells to store an odd number of data bits, performs, for each of the odd number of data bits, respective sets of strobe reads on a pair of memory cells that form the at least one super cell and generates soft-bit read information corresponding to the at least one super cell based on combined cell state information obtained from the respective sets of strobe reads. The soft-bit read information can indicate a likelihood of the at least one super cell being misread and can be provided to error correction logic for use in error correction operations.

### RELATED APPLICATIONS

This application claims the benefit of U.S. Provisional Patent Application No. 63/561,623, filed Mar. 5, 2024, the entire contents of which are hereby incorporated by reference herein.

### TECHNICAL FIELD

Embodiments of the disclosure relate generally to memory sub-systems, and more specifically, relate to soft-bit read operations for super cells in a memory device of a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system in accordance with some embodiments of the present disclosure.

FIG. 1B is a block diagram of a memory device in communication with a memory sub-system controller of a memory sub-system, in accordance with some embodiments of the present disclosure.

FIG. 2 is a schematic of portions of an array of memory cells as could be used in a memory of the type described with reference to FIG. 1B in accordance with some embodiments of the present disclosure.

FIG. 3A is a schematic block diagram of a super cell including multiple memory cells associated with a common wordline, in accordance with some embodiments of the present disclosure.

FIG. 3B is a diagram illustrating three possible threshold voltage (Vt) states of each memory cell in a super cell, in accordance with some embodiments of the present disclosure.

FIGS. 4A-4C are diagrams illustrating soft-bit read operations on a super cell of a memory device using a first encoding, in accordance with some embodiments of the present disclosure.

FIGS. 5A-5C are diagrams illustrating soft-bit read operations on a super cell of a memory device using a second encoding, in accordance with some embodiments of the present disclosure.

FIG. 6 is a graph of four threshold voltage levels capable of being programmed to lower, middle, and upper portions of multiple memory cells of a super cell, in accordance with some embodiments of the present disclosure.

FIG. 7 is a graph of eight threshold voltage levels capable of being programmed to lower, middle, and upper portions of multiple memory cells of a super cell, in accordance with some embodiments of the present disclosure.

FIG. 8 is a flow diagram of an example method of performing soft-bit read operations for super cells in a memory device in accordance with some embodiments of the present disclosure.

FIG. 9 is a flow diagram of an example method of performing error correction operations for super cells in a memory device using soft-bit read information in accordance with some embodiments of the present disclosure.

FIG. 10 is a block diagram of an example computer system in which embodiments of the present disclosure can operate.

### DETAILED DESCRIPTION

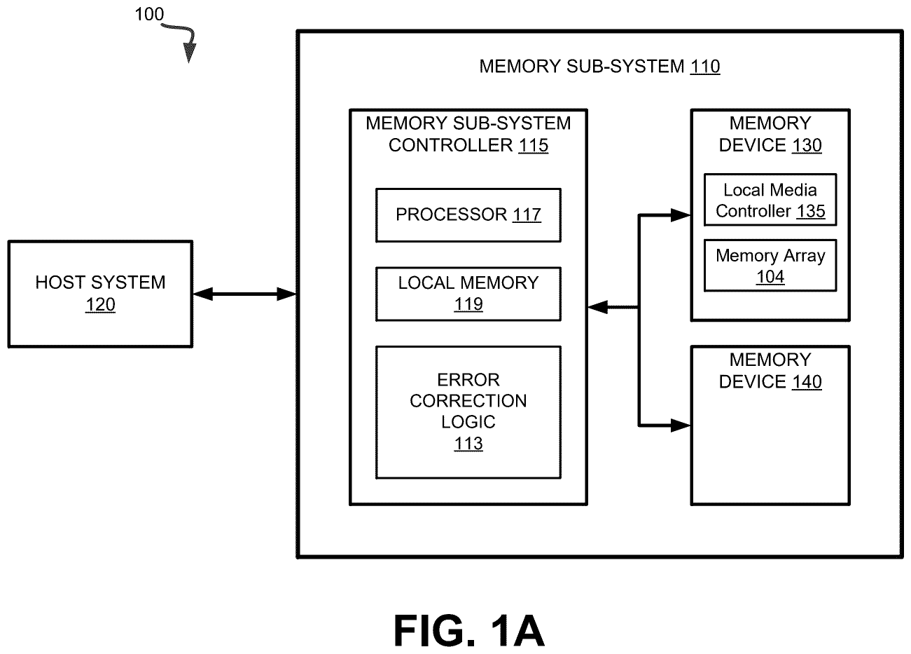

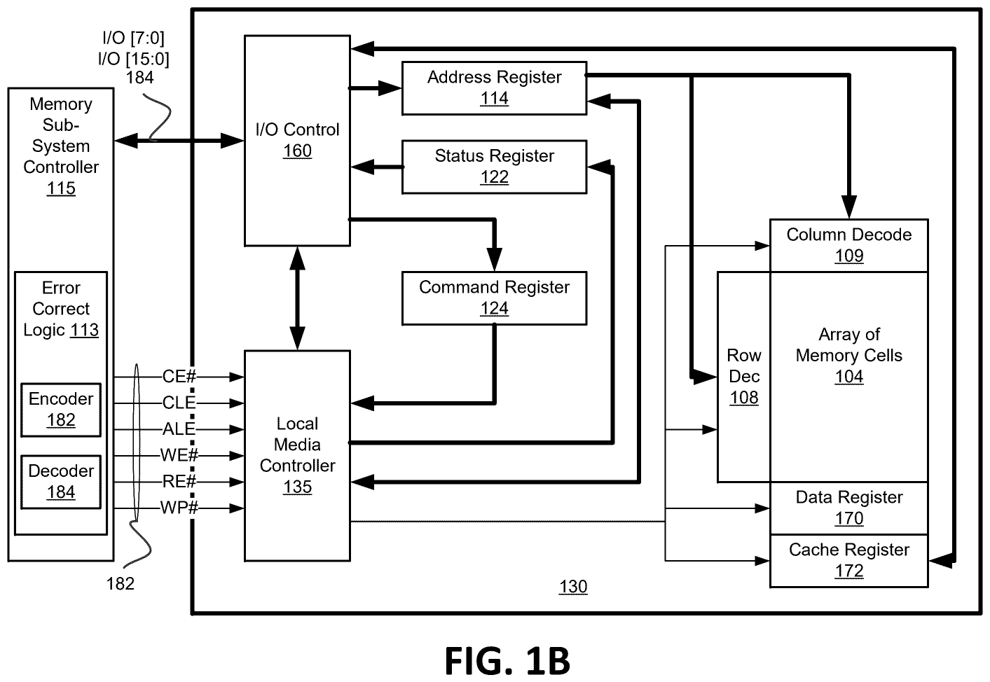

Aspects of the present disclosure are directed to soft-bit read operations for super cells in a memory device of a memory sub-system. A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high density configurations. A non-volatile memory device is a package of one or more dice, each including one or more planes. For some types of non-volatile memory devices (e.g., NAND memory), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

In certain memory devices, memory cells each store an encoding of a certain number of logical bits, such as three logical bits (i.e., when the cells configured as triple-level cell (TLC) memory cells) or four logical bits (i.e., when the cells are configured as quad-level cell (QLC) memory cells). In order to increase the storage capacity of the memory device, the number of logical bits encoded per cell can be increased without requiring additional encoding or decoding. The likelihood of encountering errors in the data increases, however, as the read window budget (RWB) becomes significantly tighter when adding additional threshold voltage (Vt) levels (e.g., going from encoding 8 logical states to encoding 16 logical states in each memory cell). The RWB refers to the amount of voltage that separates two neighboring voltage distributions of memory cells from each other on the memory device. As the RWB decreases, it can become more difficult to resolve the Vt level of transition between two logical states (e.g., data bits) of the memory cell. Overly narrow RWB can thus result in higher bit error rates when reading data out of each memory cell that has been so converted.

One approach which can be used to increase the storage capacity of a memory device without causing RWB concerns includes the use of super cells. A super cell is a group of two or more memory cells in the memory device on which an intermediate number of logical bits is encoded, such as one and half (“1.5” bits per cell), and thus three (“3”) logical bits per pair of memory cells. For example, control logic can encode a set of three logical bits (e.g., that are base two values) within a combination of a pair of memory cells (e.g., as a first threshold voltage state (or level) stored in the first memory cell and a second threshold voltage state (or level) stored in the second memory cell). Since each of these states can represent one of three different integer values (e.g., 0, 1, or 2), the combined two-state value for the combination of the two memory cells can be translated into the three logical bits (e.g., as the three least significant bits of the logical bits being programmed). This translation can be performed using an integer-to-logical value decoding table, as will be discussed below.

Even when using super cells, there remains the possibility for errors to be present in data read from the memory device (e.g., due to noise, interference, degradation). Accordingly, a decoder in the memory sub-system can be tasked with performing error correction operations to identify and correct the errors. If after performing certain hardware-based error correction operations, additional errors remain in the read data, the decoder can attempt certain soft error correction operations (e.g., using soft-bit read information provided by the memory device). The soft-bit read information can include an indication of certain memory cells in the memory device which have a higher likelihood of errors than other memory cells. Accordingly, the decoder can select specific soft error correction operations and/or focus error correction on those certain memory cells in order to improve the efficiency of the soft error correction operations. Conventional techniques for determining soft-bit read information are limited in applicability, however, to single memory cells. These techniques can include performing a series of read operations on each memory cell using different read voltage levels (i.e., strobes) and analyzing the read results to determine a statistical probability of whether each memory cell is likely to suffer a read error. Although these techniques can be useful for an individual cell, when super cells are utilized in a memory device, the soft-bit read information must reflect the likelihood of whether the combination of multiple memory cells will be misread, rather than whether the multiple memory cells will be misread individually.

Aspects of the present disclosure address the above and other deficiencies by providing soft-bit read operations for super cells in a memory device of a memory sub-system. In one embodiment, control logic of the memory device performs a multi-stage soft-bit read operation on a super cell of the memory device to determine soft-bit read information representing a probability of whether an odd number of data bits encoded in each pair of memory cells in the super cell will be misread. This soft-bit read information can be provided to a decoder in the memory sub-system and used during error correction operations performed on the data read from the memory device.

Advantages of this approach include, but are not limited to, improved performance in the memory sub-system. The approach described herein allows for the use of super cells in the memory device, which increases storage capacity, while maintaining high read accuracy and error correction capabilities. The ability to perform soft-bit read operations on super cells reduces the rate of invoking longer latency corrective read operations to obtain soft-bit information, which improves the quality of service and increases the lifespan of the memory device.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the physical host interface (e.g., PCIe or CXL interface). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

In one embodiment, the memory sub-system 110 includes a memory interface that is responsible for handling interactions of memory sub-system controller 115 with the memory devices of memory sub-system 110, such as memory device 130. For example, the memory interface can send memory access commands corresponding to requests received from host system 120 to memory device 130, such as program commands, read commands, or other commands. In addition, the memory interface can receive data from memory device 130, such as data retrieved in response to a read command or a confirmation that a program command was successfully performed. In one embodiment, the memory interface includes error correction logic 113 that performs error detection and correction operations on the data read from memory device 130. For example, the error correction logic 113 may receive soft-bit read information for super cells in memory device 130 and utilize that soft-bit read information to identify or correct errors in the data. In some embodiments, the memory sub-system controller 115 includes at least a portion of the error correction logic 113. For example, the memory sub-system controller 115 can include a processor 117 (processing device) configured to execute instructions stored in local memory 119 for performing the operations described herein. In some embodiments, the error correction logic 113 includes hardware components, such as an encoder and decoder, configured to perform the operations described herein.

In one embodiment, local media controller 135 of memory device 130 is configured to carry out soft-bit read operations on super cells of memory array 104 and provide the resulting soft-bit read information to error correction logic 113. Further details with regards to the operations of local media controller 135 and error correction logic 113 are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device. In one embodiment, memory sub-system controller 115 includes error correction logic 113. Error correction logic 113 may include encoder 182 configured to encode an odd number of data bits into a set of program states stored on a super cell of the memory array 104 and a decoder 184 configured to decode the set of program states from the super cells into the odd number of data bits.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses. In one embodiment, local media controller 135 includes corrective read module 134, which can implement the corrective read with partial block offset of memory device 130, as described herein.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 182. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 182 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 184 and outputs data to the memory sub-system controller 115 over I/O bus 184.

For example, the commands may be received over input/output (I/O) pins [7:0] of I/O bus 184 at I/O control circuitry 160 and may then be written into command register 124. The addresses may be received over input/output (I/O) pins [7:0] of I/O bus 184 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

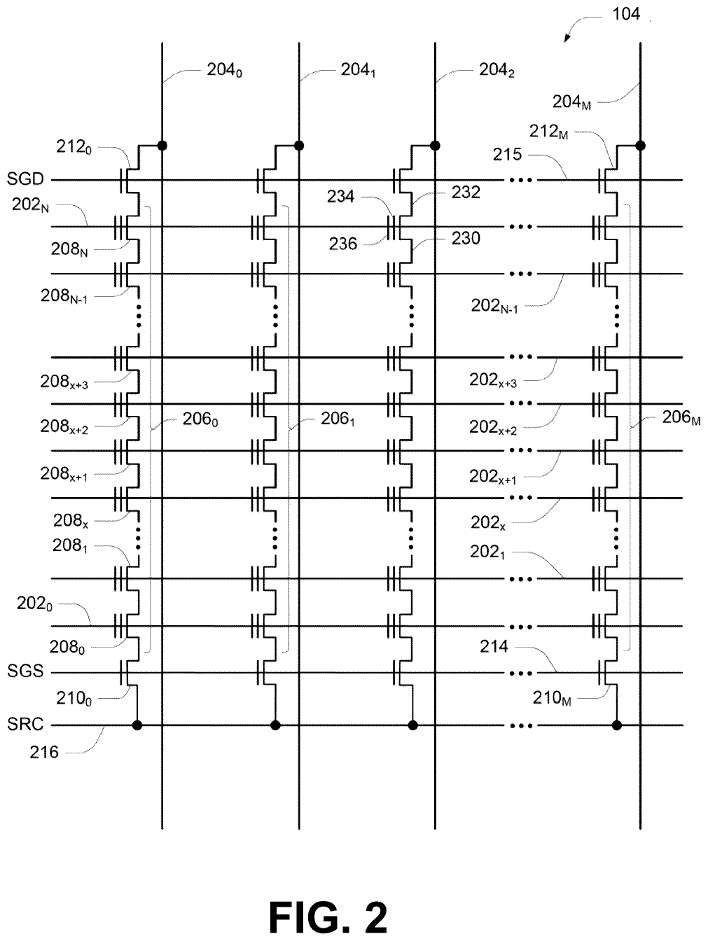

FIG. 2 is a schematic of portions of an array of memory cells 104, such as a NAND memory array, as could be used in a memory of the type described with reference to FIG. 1B according to an embodiment. Memory array 104 includes access lines, such as wordlines 202₀ to 202_{N}, and data lines, such as bit lines 204₀ to 204_{M}. The wordlines 202 can be connected to global access lines (e.g., global wordlines), not shown in FIG. 2, in a many-to-one relationship. For some embodiments, memory array 104 can be formed over a semiconductor that, for example, can be conductively doped to have a conductivity type, such as a p-type conductivity, e.g., to form a p-well, or an n-type conductivity, e.g., to form an n-well.

Memory array 104 can be arranged in rows (each corresponding to a wordline 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 104 in FIG. 2 can be a quasi-two-dimensional memory array and can have a generally planar structure, e.g., where the common source 216, NAND strings 206 and bit lines 204 extend in substantially parallel planes. Alternatively, the memory array 104 in FIG. 2 can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bit line 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bit lines 204 (e.g., bit lines 204₀, 204₂, 204₄, etc.) can be one physical page of the memory cells 208 (e.g., even memory cells) while memory cells 208 commonly connected to wordline 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2, it is apparent from the figure that the bit lines 204 of the array of memory cells 104 can be numbered consecutively from bit line 204₀ to bit line 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

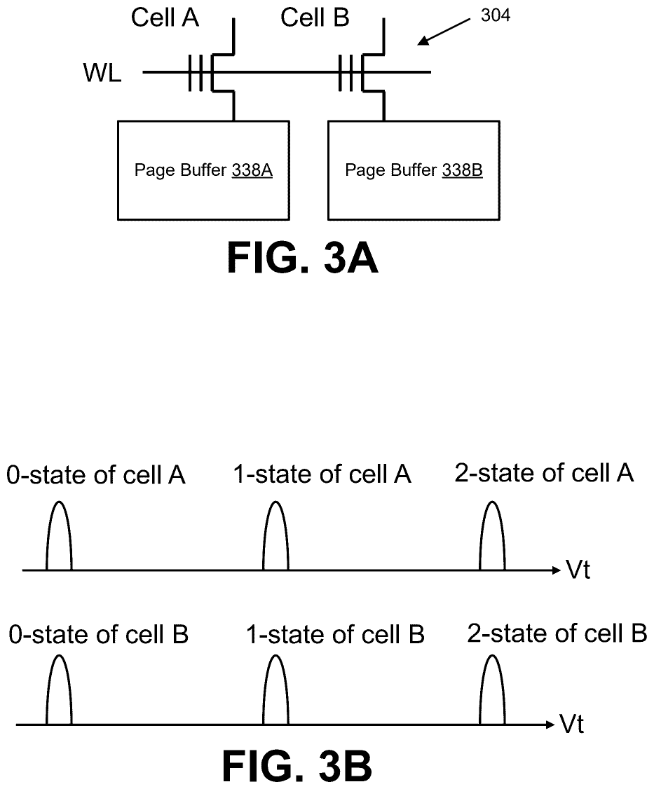

FIG. 3A is a schematic block diagram of a super cell including multiple memory cells associated with a common wordline, in accordance with some embodiments of the present disclosure. A super cell, such as super cell 304, is a group of two or more memory cells in the memory device on which an intermediate number of logical bits is encoded, such as one and half (“1.5” bits per cell), and thus three (“3”) logical bits per pair of memory cells. For example, control logic can encode a set of three logical bits (e.g., that are base two values) within a combination of a pair of memory cells (e.g., as a first threshold voltage state (or level) stored in the first memory cell and a second threshold voltage state (or level) stored in the second memory cell). Since each of these states can represent one of three different integer values (e.g., 0, 1, or 2), the combined two-state value for the combination of the two memory cells can be translated into the three logical bits (e.g., as the three least significant bits of the logical bits being programmed). This translation can be performed using an integer-to-logical value decoding table, as will be discussed below.

As illustrated in FIG. 3A, super cell 304 includes a pair of memory cells, including a first memory cell (Cell A) and a second memory cell (Cell B) that are coupled to a single word line (WL). Depending on the embodiment, the super cell 304 could be formed from any of the memory cells in memory array 104, as described with respect to FIG. 1B or FIG. 2. In at least some embodiments, a bit line from the first memory cell (Cell A) is coupled with a first page buffer 338A and a bit line from the second memory cell (Cell B) is coupled with a second page buffer 338B. Control logic in the memory device 130, such as local media controller 135, can be coupled with the first and second page buffers 338A and 338B in these embodiments to sense various Vt states (e.g., the first Vt state and the second Vt state) from the first and second memory cells, which can be temporarily stored in the first and second page buffers 338A and 338B, respectively.

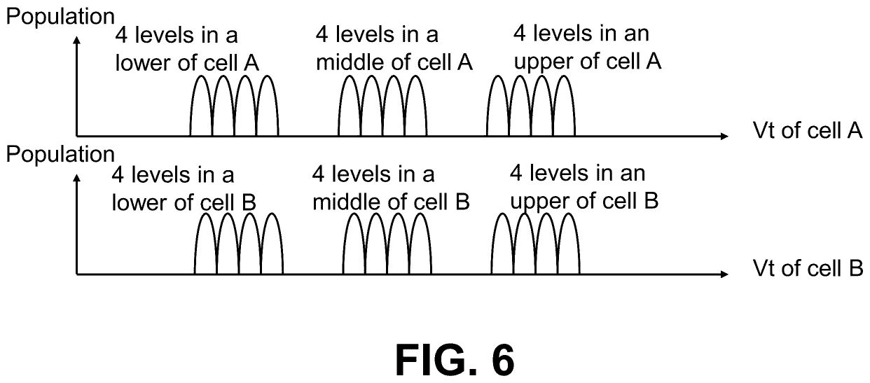

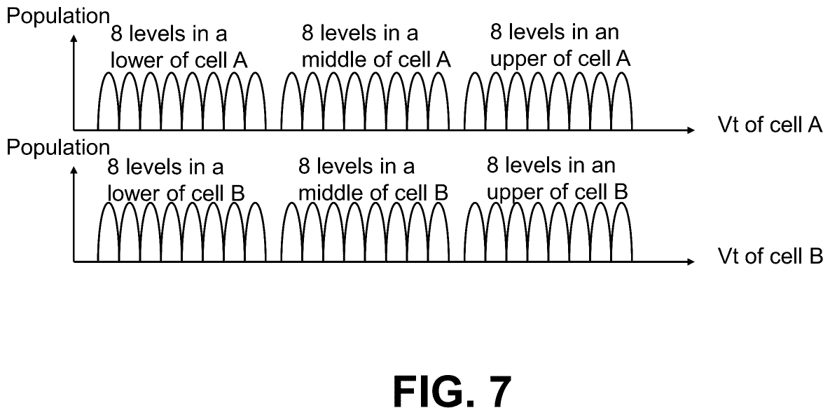

FIG. 3B is a diagram illustrating three possible threshold voltage (Vt) states of each memory cell in a super cell, in accordance with some embodiments of the present disclosure. For example, the Vt state (or level) of each of Cell A and Cell B can be located in a lower voltage range (0-state), a middle voltage range (1-state), or an upper voltage range (2-state). These lower, middle, and upper Vt states can be encoded as discussed in more detail with reference to FIG. 6 (TLC embodiment) and FIG. 7 (QLC embodiment). In one embodiment, these 0-state, 1-state, and 2-state Vt values can be converted to integer values. In various embodiments, the control logic can cause a first Vt state of the first memory cell to be converted to a first integer value. Further, the control logic can cause a second Vt state of the second memory cell to be converted to a second integer value. The control logic can then translate, using a decoding table such as Table 1, the combination of the first integer value and the second integer value to a set of three logical bits corresponding to the combination of the first and second Vt states.

TABLE 1

| | |
|---|---|
| Dual-Cell Vt State | Logical Bits (Data) |

| Cell A | Cell B | Bit_0 | Bit_1 | Bit_2 |
|---|---|---|---|---|
| 0 | 0 | 1 | 1 | 1 |
| 0 | 1 | 0 | 1 | 1 |
| 0 | 2 | 0 | 0 | 1 |
| 1 | 0 | 0 | 1 | 0 |
| 1 | 1 | 1 | 1 | 0 |
| 1 | 2 | 1 | 0 | 1 |
| 2 | 0 | 0 | 0 | 0 |
| 2 | 1 | 1 | 0 | 0 |
| 2 | 2 | 1 | 1 | 0 |

In some embodiments, the 0-State is less than −1 volt (V), the 1-State is between 0.3-1.2V, and the 2-State is between 2.0 and 2.9V in a three-level memory cell, although other voltage ranges are envisioned that can be stored as three Vt levels, and buffered in the one or more page buffer(s) while being programmed to or read out of the memory cell. These voltage ranges may especially be shifted and broadened to make room for 12 Vt states (FIG. 6) in TLCs or for 24 Vt states (FIG. 7) in QLCs. Table 1 illustrates a decoding table according one of many possible embodiments of decoding, which the control logic can access in order to perform a translation between the combination of the first and second integer values and the three logical bits. In some embodiments, while there are nine possible combinations of the three logical bits, only eight combinations may be used for logical data states. Thus, in the embodiment of Table 1, if Cells A and B express the “1-1” state as illustrated in Table 1, the resulting “1 1 0” logical bit values may not be used for programming.

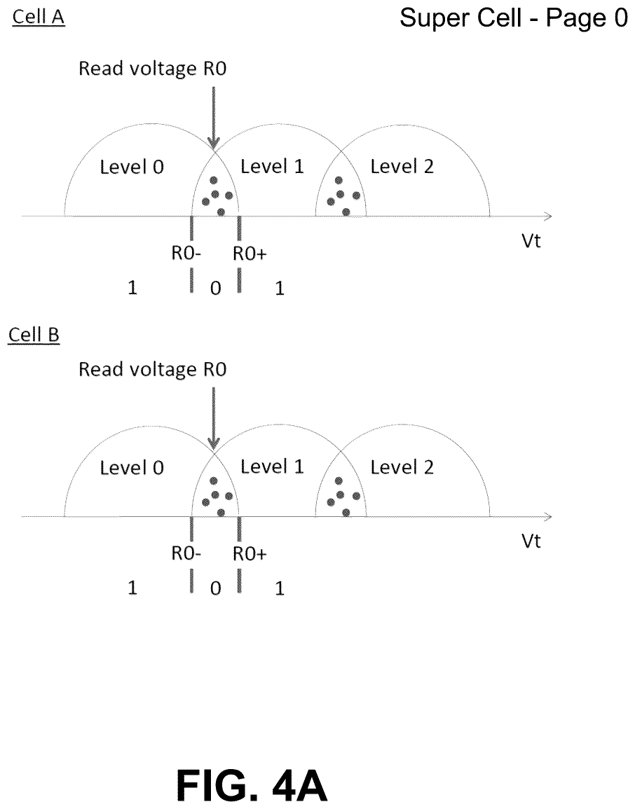

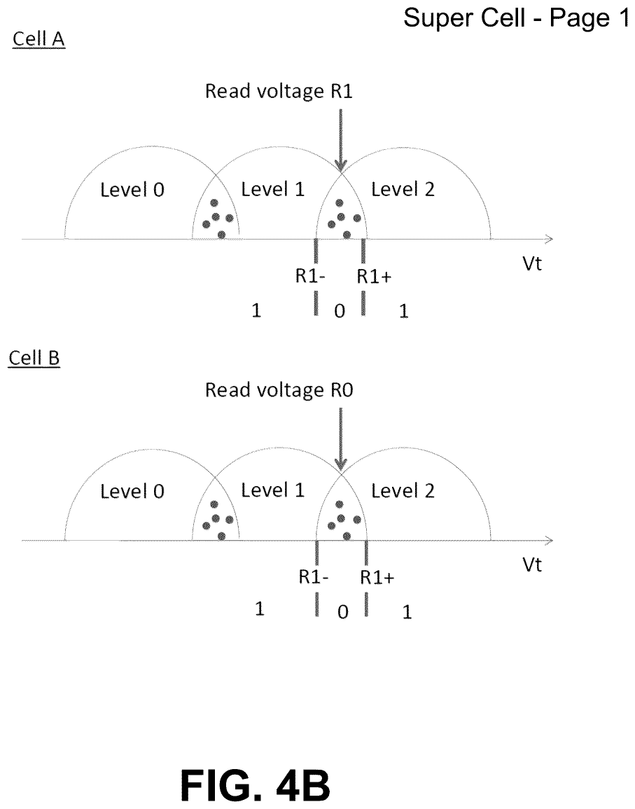

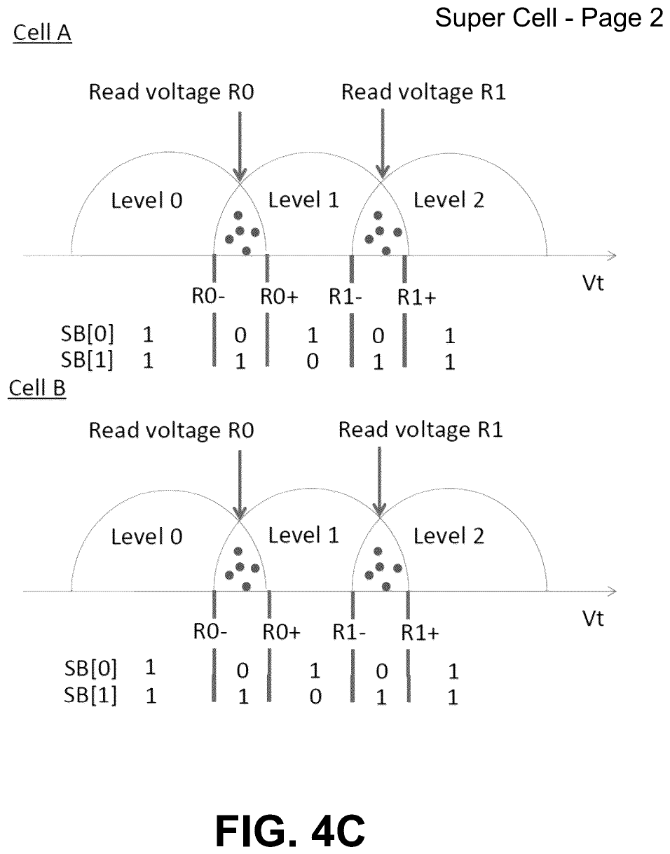

FIGS. 4A-4C are diagrams illustrating soft-bit read operations on a super cell of a memory device using the encoding in Table 1 (and where the “1-1” state and resulting “1 1 0” logical bit values are not used for programming), in accordance with some embodiments of the present disclosure. In one embodiment, a memory device, such as memory device 130, includes a memory array 104 that is configured with a number of super cells, such as super cell 304. As described above, a given wordline (WL) in the memory array 104 can include a set of associated super cells, where each super cell stores an odd number of logical bits (e.g., 3 logical bits) across a pair of memory cells that make up the super cell. Thus, the set of super cells associated with the wordline collectively store an odd number of logical pages of data (e.g., 3 logical pages). Control logic on the memory device, such as memory sub-system controller 135, can perform a multi-stage soft-bit read operation on a super cell of the memory device to determine soft-bit read information for each of the three logical pages representing a probability of whether data bits in the corresponding page will be misread.

FIG. 4A illustrates the first stage of the multi-stage soft-bit read operation used to determine soft-bit read information for a first logical page (e.g., page 0). In one embodiment, the control logic initiates a soft-bit read on Cell A using a set of read voltage levels associated with read voltage level R0. R0 can be selected to fall between the Level 0 and Level 1 distributions. For example, the control logic can cause read operations to be performed on Cell A using read voltage levels R0− and R0+. Read voltage levels R0− and R0+ can be offset from read voltage level R0 (i.e., less than and greater than R0, respectively) by fixed amounts that can vary depending on the implementation. If the threshold voltage of Cell A is less than R0− (i.e., within the Level 0 distribution) or greater than R0+ (i.e., within the Level 1 or Level 2 distributions), the control logic determines a result of “1.” Conversely, if the threshold voltage of Cell A is greater than R0− and less than R0+ (i.e., within the overlapping voltage range of the Level 0 and Level 1 distributions), the control logic determines a result of “0.” Memory cells in this overlapping voltage range are more likely to be misread, and thus are identified by the soft-bit read information.

Next, the control logic initiates a soft-bit read on Cell B using the same set of read voltage levels associated with read voltage level R0 (i.e., R0− and R0+). If the threshold voltage of Cell B is less than R0− (i.e., within the Level 0 distribution) or greater than R0+ (i.e., within the Level 1 or Level 2 distributions), the control logic determines a result of “1.” Conversely, if the threshold voltage of Cell B is greater than R0− and less than R0+ (i.e., within the overlapping voltage range of the Level 0 and Level 1 distributions), the control logic determines a result of “0.” The result for Cell A and the result for Cell B can be combined to form the soft-bit read information for the first logical page (e.g., page 0) of the super cell. For example, if the results for Cell A and Cell B are both “1,” the combined soft-bit read information can be a two bit value “11,” which can be decoded as a low likelihood that page 0 of the super cell will be misread. If the result for one of Cell A or Cell B is “1” and the other result is “0,” the combined soft-bit read information can be a two bit value “10,” which can be decoded as a medium likelihood that page 0 of the super cell will be misread. If the results for Cell A and Cell B are both “0,” the combined soft-bit read information can be a two bit value “01,” which can be decoded as a high likelihood that page 0 of the super cell will be misread. These results are summarized in Table 2.

TABLE 2

| | | Soft-bit read |
|---|---|---|
| Result of Cell A | Result of Cell B | information for page 0 |
| 1 | 1 | 11 (low) |
| 1 | 0 | 10 (med) |
| 0 | 1 | 10 (med) |
| 0 | 0 | 01 (high) |

FIG. 4B illustrates the second stage of the multi-stage soft-bit read operation used to determine soft-bit read information for a second logical page (e.g., page 1). In one embodiment, the control logic initiates a soft-bit read on Cell A using a set of read voltage levels associated with read voltage level R1. R1 can be selected to fall between the Level 1 and Level 2 distributions. For example, the control logic can cause read operations to be performed on Cell A using read voltage levels R1− and R1+. Read voltage levels R1− and R1+ can be offset from read voltage level R1 (i.e., less than and greater than R1, respectively) by fixed amounts that can vary depending on the implementation. If the threshold voltage of Cell A is less than R1− (i.e., within the Level 0 or Level 1 distributions) or greater than R1+ (i.e., within the Level 2 distribution), the control logic determines a result of “1.” Conversely, if the threshold voltage of Cell A is greater than R1− and less than R1+ (i.e., within the overlapping voltage range of the Level 1 and Level 2 distributions), the control logic determines a result of “0.” Memory cells in this overlapping voltage range are more likely to be misread, and thus are identified by the soft-bit read information.

Next, the control logic initiates a soft-bit read on Cell B using the same set of read voltage levels associated with read voltage level R1 (i.e., R1− and R1+). If the threshold voltage of Cell B is less than R1− (i.e., within the Level 0 or Level 1 distributions) or greater than R1+ (i.e., within the Level 2 distribution), the control logic determines a result of “1.” Conversely, if the threshold voltage of Cell B is greater than R1− and less than R1+ (i.e., within the overlapping voltage range of the Level 1 and Level 2 distributions), the control logic determines a result of “0.” The result for Cell A and the result for Cell B can be combined to form the soft-bit read information for the second logical page (e.g., page 1) of the super cell. For example, if the results for Cell A and Cell B are both “1,” the combined soft-bit read information can be a two bit value “11,” which can be decoded as a low likelihood that page 0 of the super cell will be misread. If the result for one of Cell A or Cell B is “1” and the other result is “0,” the combined soft-bit read information can be a two bit value “10,” which can be decoded as a medium likelihood that page 0 of the super cell will be misread. If the results for Cell A and Cell B are both “0,” the combined soft-bit read information can be a two bit value “01,” which can be decoded as a high likelihood that page 0 of the super cell will be misread. These results are summarized in Table 3.

TABLE 3

| | | Soft-bit read |
|---|---|---|
| Result of Cell A | Result of Cell B | information for page 1 |
| 1 | 1 | 11 (low) |
| 1 | 0 | 10 (med) |
| 0 | 1 | 10 (med) |
| 0 | 0 | 01 (high) |

FIG. 4C illustrates the third stage of the multi-stage soft-bit read operation used to determine soft-bit read information for a third logical page (e.g., page 2). In one embodiment, the third stage can include two steps. In the first step, the control logic initiates a soft-bit read on Cell A using the first set of read voltage levels associated with read voltage level R0 (i.e., R0− and R0+) and the second set of read voltage levels associated with read voltage level R1 (i.e., R1− and R1+). If the threshold voltage of Cell A is less than R0−, greater than R0+ and less than R1−, or greater than R1+, the control logic determines a SB[0] result of “1.” Conversely, if the threshold voltage of Cell A is greater than R0− and less than R0+ (i.e., within the overlapping voltage range of the Level 0 and Level 1 distributions) or greater than R1− and less than R1+ (i.e., within the overlapping voltage range of the Level 1 and Level 2 distributions), the control logic determines a SB[0] result of “0.”

Next, the control logic initiates a soft-bit read on Cell B using the first set of read voltage levels associated with read voltage level R0 (i.e., R0− and R0+) and the second set of read voltage levels associated with read voltage level R1 (i.e., R1− and R1+). If the threshold voltage of Cell A is less than R0−, greater than R0+ and less than R1−, or greater than R1+, the control logic determines a SB[0] result of “1.” Conversely, if the threshold voltage of Cell A is greater than R0− and less than R0+ (i.e., within the overlapping voltage range of the Level 0 and Level 1 distributions) or greater than R1− and less than R1+ (i.e., within the overlapping voltage range of the Level 1 and Level 2 distributions), the control logic determines a SB[0] result of “0.” The SB[0] result for Cell A and the SB[0] result for Cell B can be combined to form an initial soft-bit read information for the third logical page (e.g., page 2) of the super cell. For example, if the SB[0] results for Cell A and Cell B are both “1,” the combined soft-bit read information can be a two bit value “11,” which can be decoded as a low likelihood that page 0 of the super cell will be misread. If the SB[0] result for one of Cell A or Cell B is “1” and the other result is “0,” the combined soft-bit read information can be a two bit value “10,” which can be decoded as a medium likelihood that page 0 of the super cell will be misread. If the SB[0] results for Cell A and Cell B are both “0,” the combined soft-bit read information can be a two bit value “01,” which can be decoded as a high likelihood that page 0 of the super cell will be misread. These results are summarized in Table 4.

TABLE 4

| | | Initial soft-bit read |
|---|---|---|
| SB[0] of Cell A | SB[1] of Cell B | information for page 2 |
| 1 | 1 | 11 (low) |
| 1 | 0 | 10 (med) |
| 0 | 1 | 10 (med) |
| 0 | 0 | 01 (high) |

In the second step of the third stage, the control logic initiates a soft-bit read on Cell A using the set of read voltage levels R0+ and R1− If the threshold voltage of Cell A is less than R0+ or greater than R1−, the control logic determines a SB[1] result of “1.” Conversely, if the threshold voltage of Cell A is greater than R0+ and less than R1−, the control logic determines a SB[1] result of “0.”

Next, the control logic initiates a soft-bit read on Cell B using the set of read voltage levels R0+ and R1−. If the threshold voltage of Cell B is less than R0+ or greater than R1−, the control logic determines a SB[1] result of “1.” Conversely, if the threshold voltage of Cell B is greater than R0+ and less than R1−, the control logic determines a SB[1] result of “0.” The SB[1] result for Cell A and the SB[1] result for Cell B can be used to update the initial soft-bit read information and form a final soft-bit read information for the third logical page (e.g., page 2) of the super cell. For example, if the SB[1] results for Cell A and Cell B are both “0,” an initial soft-bit read information of “11” can be updated to a two bit value “00,” which can be viewed as a definitive indication that one or more bits of the three logical bits are wrong. In all other cases, no updated is made, and the initial soft-bit read information can be used as the final soft-bit read information. These results are summarized in Table 5.

TABLE 5

| | | Final Soft-bit read |
|---|---|---|
| SB[1] of Cell A | SB[0] of Cell B | information for page 2 |
| 0 | 0 | 11 → 00 |

| | |
|---|---|
| All other cases | No update |

Once the multi-stage soft-bit read operation is complete, the control logic will have soft-bit read information for each of the three logical pages (i.e., a separate two bit value for each of the three logical pages). The control logic can provide this soft-bit read information, representing a relative probability or likelihood of whether data bits in the corresponding pages will be misread, to a requestor, such as error correction logic 113. Depending on the embodiment, the control logic can provide the soft-bit read information either in response to a request or unprompted. In one embodiment, the two bit value for each logical page is provided to the requestor separately. For example, if the error correction logic 113 issues a command for a page 0 read, the two bit value for page 0 can be returned. Similarly, if the error correction logic issues a command for a page 1 or page 2 read, the corresponding two bit value for page 1 or page 2 can be returned. Error correction logic 113 can receive the soft-bit read information for super cells in memory device 130 and utilize that soft-bit read information to identify or correct errors in the data. For example, error correction logic 113 can select specific soft error correction operations and/or focus error correction on those certain super cells identified as more likely to be misread in order to improve the efficiency of the soft error correction operations.

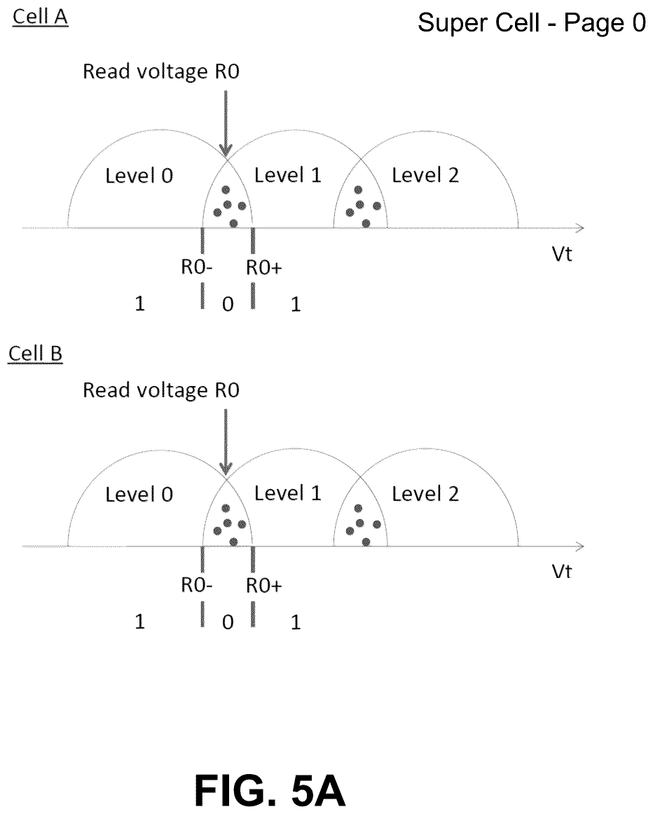

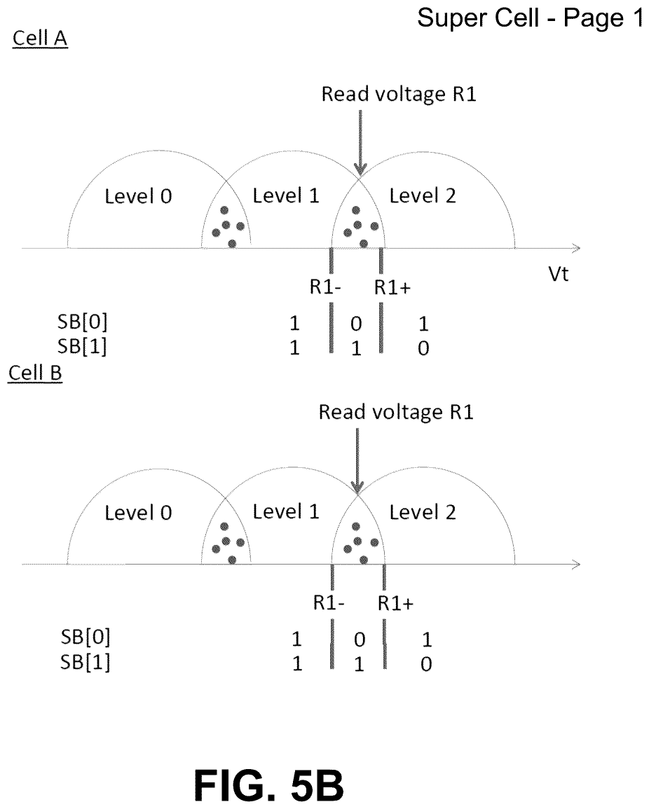

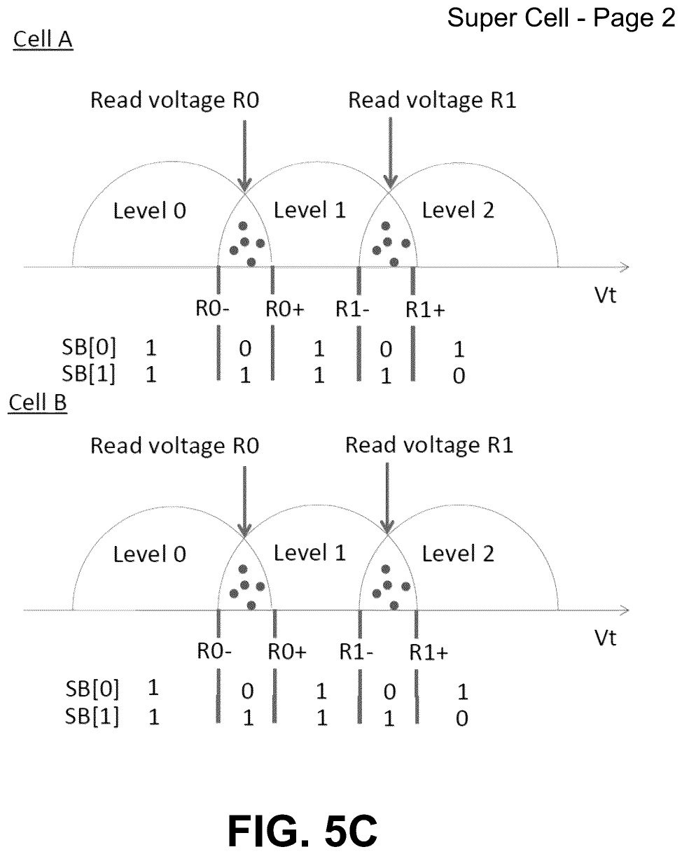

FIGS. 5A-5C are diagrams illustrating soft-bit read operations on a super cell of a memory device using the encoding in Table 1 (but where the “2-2” state and resulting “1 1 0” logical bit values are not used for programming), in accordance with some embodiments of the present disclosure. Depending on where the unused dual-cell Vt state resides, a change to the soft-bit read algorithm may also be required. In the case where the “2-2” state is unused, the soft-bit read algorithm for page 1 is able to identify an existence of the “2-2” state. In the case where the “1-1” state is unused, as described above, the soft-bit read algorithm for page 1 is not able to identify an existence of the “1-1” state. In one embodiment, a memory device, such as memory device 130, includes a memory array 104 that is configured with a number of super cells, such as super cell 304. As described above, a given wordline (WL) in the memory array 104 can include a set of associated super cells, where each super cell stores an odd number of logical bits (e.g., 3 logical bits) across a pair of memory cells that make up the super cell. Thus, the set of super cells associated with the wordline collectively store an odd number of logical pages of data (e.g., 3 logical pages). Control logic on the memory device, such as memory sub-system controller 135, can perform a multi-stage soft-bit read operation on a super cell of the memory device to determine soft-bit read information for each of the three logical pages representing a probability of whether data bits in the corresponding page will be misread.

FIG. 5A illustrates the first stage of the multi-stage soft-bit read operation used to determine soft-bit read information for a first logical page (e.g., page 0). In one embodiment, the control logic initiates a soft-bit read on Cell A using a set of read voltage levels associated with read voltage level R0. R0 can be selected to fall between the Level 0 and Level 1 distributions. For example, the control logic can cause read operations to be performed on Cell A using read voltage levels R0− and R0+. Read voltage levels R0− and R0+ can be offset from read voltage level R0 (i.e., less than and greater than R0, respectively) by fixed amounts that can vary depending on the implementation. If the threshold voltage of Cell A is less than R0− (i.e., within the Level 0 distribution) or greater than R0+ (i.e., within the Level 1 or Level 2 distributions), the control logic determines a result of “1.” Conversely, if the threshold voltage of Cell A is greater than R0− and less than R0+ (i.e., within the overlapping voltage range of the Level 0 and Level 1 distributions), the control logic determines a result of “0.” Memory cells in this overlapping voltage range are more likely to be misread, and thus are identified by the soft-bit read information.

Next, the control logic initiates a soft-bit read on Cell B using the same set of read voltage levels associated with read voltage level R0 (i.e., R0− and R0+). If the threshold voltage of Cell B is less than R0− (i.e., within the Level 0 distribution) or greater than R0+ (i.e., within the Level 1 or Level 2 distributions), the control logic determines a result of “1.” Conversely, if the threshold voltage of Cell B is greater than R0− and less than R0+ (i.e., within the overlapping voltage range of the Level 0 and Level 1 distributions), the control logic determines a result of “0.” The result for Cell A and the result for Cell B can be combined to form the soft-bit read information for the first logical page (e.g., page 0) of the super cell. For example, if the results for Cell A and Cell B are both “1,” the combined soft-bit read information can be a two bit value “11,” which can be decoded as a low likelihood that page 0 of the super cell will be misread. If the result for one of Cell A or Cell B is “1” and the other result is “0,” the combined soft-bit read information can be a two bit value “10,” which can be decoded as a medium likelihood that page 0 of the super cell will be misread. If the results for Cell A and Cell B are both “0,” the combined soft-bit read information can be a two bit value “01,” which can be decoded as a high likelihood that page 0 of the super cell will be misread. These results are summarized in Table 6.

TABLE 6

| | | Soft-bit read |
|---|---|---|
| Result of Cell A | Result of Cell B | information for page 0 |
| 1 | 1 | 11 (low) |
| 1 | 0 | 10 (med) |
| 0 | 1 | 10 (med) |
| 0 | 0 | 01 (high) |

FIG. 5B illustrates the second stage of the multi-stage soft-bit read operation used to determine soft-bit read information for a second logical page (e.g., page 1). In one embodiment, the second stage can include two steps. In the first step, the control logic initiates a soft-bit read on Cell A using the set of read voltage levels associated with read voltage level R1 (i.e., R1− and R1+). If the threshold voltage of Cell A is less than R1− or greater than R1+, the control logic determines a SB[0] result of “1.” Conversely, if the threshold voltage of Cell A is greater than R1− and less than R1+ (i.e., within the overlapping voltage range of the Level 1 and Level 2 distributions), the control logic determines a SB[0] result of “0.”

Next, the control logic initiates a soft-bit read on Cell B using the same set of read voltage levels associated with read voltage level R1 (i.e., R1− and R1+). If the threshold voltage of Cell A is less than R1− or greater than R1+, the control logic determines a SB[0] result of “1.” Conversely, if the threshold voltage of Cell A is greater than R1− and less than R1+ (i.e., within the overlapping voltage range of the Level 1 and Level 2 distributions), the control logic determines a SB[0] result of “0.” The SB[0] result for Cell A and the SB[0] result for Cell B can be combined to form an initial soft-bit read information for the second logical page (e.g., page 1) of the super cell. For example, if the SB[0] results for Cell A and Cell B are both “1,” the combined soft-bit read information can be a two bit value “11,” which can be decoded as a low likelihood that page 0 of the super cell will be misread. If the SB[0] result for one of Cell A or Cell B is “1” and the other result is “0,” the combined soft-bit read information can be a two bit value “10,” which can be decoded as a medium likelihood that page 0 of the super cell will be misread. If the SB[0] results for Cell A and Cell B are both “0,” the combined soft-bit read information can be a two bit value “01,” which can be decoded as a high likelihood that page 0 of the super cell will be misread. These results are summarized in Table 7.

TABLE 7

| | | Initial soft-bit read |
|---|---|---|
| SB[0] of Cell A | SB[0] of Cell B | information for page 1 |
| 1 | 1 | 11 (low) |
| 1 | 0 | 10 (med) |
| 0 | 1 | 10 (med) |
| 0 | 0 | 01 (high) |

In the second step of the second stage, the control logic initiates a soft-bit read on Cell A using the read voltage level R1+. If the threshold voltage of Cell A is less than R1+, the control logic determines a SB[1] result of “1.” Conversely, if the threshold voltage of Cell A is greater than R1+, the control logic determines a SB[1] result of “0.”

Next, the control logic initiates a soft-bit read on Cell B using the read voltage level R1+. If the threshold voltage of Cell A is less than R1+, the control logic determines a SB[1] result of “1.” Conversely, if the threshold voltage of Cell A is greater than R1+, the control logic determines a SB[1] result of “0.” The SB[1] result for Cell A and the SB[1] result for Cell B can be used to update the initial soft-bit read information and form a final soft-bit read information for the second logical page (e.g., page 1) of the super cell. For example, if the SB[1] results for Cell A and Cell B are both “0,” an initial soft-bit read information of “11” can be updated to a two bit value “00.” In all other cases, no updated is made, and the initial soft-bit read information can be used as the final soft-bit read information. These results are summarized in Table 8.

TABLE 8

| | | Final Soft-bit read |
|---|---|---|
| SB[1] of Cell A | SB[0] of Cell B | information for page 2 |
| 0 | 0 | 11 → 00 |

| | |
|---|---|
| All other cases | No update |

FIG. 5C illustrates the third stage of the multi-stage soft-bit read operation used to determine soft-bit read information for a second logical page (e.g., page 1). In one embodiment, the third stage can include two steps. In the first step, the control logic initiates a soft-bit read on Cell A using the first set of read voltage levels associated with read voltage level R0 (i.e., R0− and R0+) and the second set of read voltage levels associated with read voltage level R1 (i.e., R1− and R1+). If the threshold voltage of Cell A is less than R0−, greater than R0+ and less than R1−, or greater than R1+, the control logic determines a SB[0] result of “1.” Conversely, if the threshold voltage of Cell A is greater than R0− and less than R0+ (i.e., within the overlapping voltage range of the Level 0 and Level 1 distributions) or greater than R1− and less than R1+ (i.e., within the overlapping voltage range of the Level 1 and Level 2 distributions), the control logic determines a SB[0] result of “0.”

Next, the control logic initiates a soft-bit read on Cell B using the first set of read voltage levels associated with read voltage level R0 (i.e., R0− and R0+) and the second set of read voltage levels associated with read voltage level R1 (i.e., R1− and R1+). If the threshold voltage of Cell A is less than R0−, greater than R0+ and less than R1−, or greater than R1+, the control logic determines a SB[0] result of “1.” Conversely, if the threshold voltage of Cell A is greater than R0− and less than R0+ (i.e., within the overlapping voltage range of the Level 0 and Level 1 distributions) or greater than R1− and less than R1+ (i.e., within the overlapping voltage range of the Level 1 and Level 2 distributions), the control logic determines a SB[0] result of “0.” The SB[0] result for Cell A and the SB[0] result for Cell B can be combined to form an initial soft-bit read information for the third logical page (e.g., page 2) of the super cell. For example, if the SB[0] results for Cell A and Cell B are both “1,” the combined soft-bit read information can be a two bit value “11,” which can be decoded as a low likelihood that page 0 of the super cell will be misread. If the SB[0] result for one of Cell A or Cell B is “1” and the other result is “0,” the combined soft-bit read information can be a two bit value “10,” which can be decoded as a medium likelihood that page 0 of the super cell will be misread. If the SB[0] results for Cell A and Cell B are both “0,” the combined soft-bit read information can be a two bit value “01,” which can be decoded as a high likelihood that page 0 of the super cell will be misread. These results are summarized in Table 9.

TABLE 9

| | | Initial Soft-bit read |
|---|---|---|
| SB[0] of Cell A | SB[1] of Cell B | information for page 2 |
| 1 | 1 | 11 (low) |
| 1 | 0 | 10 (med) |
| 0 | 1 | 10 (med) |
| 0 | 0 | 01 (high) |

In the second step of the second stage, the control logic initiates a soft-bit read on Cell A using the read voltage level R1+ If the threshold voltage of Cell A is less than R1+, the control logic determines a SB[1] result of “1.” Conversely, if the threshold voltage of Cell A is greater than R1+, the control logic determines a SB[1] result of “0.”

Next, the control logic initiates a soft-bit read on Cell B using the read voltage level R1+. If the threshold voltage of Cell B is less than R1+, the control logic determines a SB[1] result of “1.” Conversely, if the threshold voltage of Cell B is greater than R1+, the control logic determines a SB[1] result of “0.” The SB[1] result for Cell A and the SB[1] result for Cell B can be used to update the initial soft-bit read information and form a final soft-bit read information for the third logical page (e.g., page 3) of the super cell. For example, if the SB[1] results for Cell A and Cell B are both “0,” an initial soft-bit read information of “11” can be updated to a two bit value “00.” In all other cases, no updated is made, and the initial soft-bit read information can be used as the final soft-bit read information. These results are summarized in Table 10.

TABLE 10

| | | Final Soft-bit read |
|---|---|---|
| SB[1] of Cell A | SB[0] of Cell B | information for page 2 |
| 0 | 0 | 11 → 00 |

| | |
|---|---|
| All other cases | No update |

Once the multi-stage soft-bit read operation is complete, the control logic will have soft-bit read information for each of the three logical pages (i.e., a separate two bit value for each of the three logical pages). The control logic can provide this soft-bit read information, representing a relative probability or likelihood of whether data bits in the corresponding pages will be misread, to a requestor, such as error correction logic 113. Depending on the embodiment, the control logic can provide the soft-bit read information either in response to a request or unprompted. Error correction logic 113 can receive the soft-bit read information for super cells in memory device 130 and utilize that soft-bit read information to identify or correct errors in the data. For example, error correction logic 113 can select specific soft error correction operations and/or focus error correction on those certain super cells identified as more likely to be misread in order to improve the efficiency of the soft error correction operations.

FIG. 6 is a graph of four threshold voltage levels capable of being programmed to lower, middle, and upper portions of multiple memory cells of a super cell, in accordance with some embodiments of the present disclosure. Three and a half (“3.5”) logical bits can be encoded per cell by encoding 7 bits in a pair of TLC memory cells, each having 12 Vt states. A total of 144 (e.g., 12×12) discrete Vt states are possible in two different cells, which can be a pair of adjacent memory cells that form a super cell. Of the 144 Vt states, 128 combined Vt states can be used to express 7 logical bits. Unlike encoding 3 logical bits or 4 logical bits per cell, an encoding/decoding scheme is employed to control read and program operations with 12 Vt states encoded in each of the pair of memory cells. From 7 logical bits of user data, two 4-bits of control data would need to be employed, one for the first memory cell and another for the second memory cell, which imparts a heavy cost for encoding and decoding.

Instead of employing 128 Vt states to encode/decode all 7 logical bits, the first memory cell can encode two (“2”) logical bits that do not need to be combined with data encoded in another cell and 1.5 logical bits that are to be combined with logical bits encoded in the second memory cell. Similarly, the second memory cell can store two (“2”) logical bits that do not need to be combined with logical bits encoded in another cell and 1.5 logical bits that are to be combined with the 1.5 logical bits encoded in the first memory cell. Thus, in one embodiment, a set of lower, middle and upper states of Cell A can be combined with that of Cell B in order to express the first 3 bits (e.g., Page 0-Page 2) of the 7 logical bits. In one embodiment, the soft-bit read information for these bits can be determined using one of the approaches described above with respect to FIGS. 4A-4C or FIGS. 5A-5C. In addition, a set of four levels in Cell A expresses the next 2 logical bits (e.g., Page 3-Page 4) and a set of four levels in Cell B expresses the final 2 logical bits (e.g., Page 5-Page 6). In one embodiment, the soft-bit read information for these logical bits can be determined in a legacy manner.

FIG. 7 is a graph of eight threshold voltage levels capable of being programmed to lower, middle, and upper portions of multiple memory cells of a super cell, in accordance with some embodiments of the present disclosure. Four and a half (“4.5”) bits per cell can be encoded per cell by encoding 9 bits in a pair of QLC memory cells, each having 24 Vt states. A total of 576 (e.g., 24×24) discrete Vt states are possible in two different cells, which can be a pair of adjacent memory cells that form a super cell. Of the 576 Vt states, 512 combined Vt states can be used to express 9 logical bits. Unlike encoding 4 logical bits or 5 logical bits per cell, an encoding/decoding scheme is employed to control read and program operations with 24 Vt states stored to each of the pair of memory cells. From 9 logical bits of user data, two 5-bits of control data would need to be employed, one for the first memory cell and another for the second memory cell, which imparts a heavy cost for encoding and decoding.

Instead of employing 512 Vt states to encode/decode all 9 logical bits, the first memory cell can store three (“3”) logical bits that do not need to be combined with logical bits of another cell and 1.5 logical bits that are to be combined with logical bits of the second memory cell. Similarly, the second memory cell can store three (“3”) logical bits that do not need to be combined with logical bits of another cell and 1.5 logical bits that are to be combined with the 1.5 logical bits of the first memory cell. Thus, in one embodiment, a set of lower, middle and upper states of Cell A can be combined with that of Cell B in order to express the first 3 bits (e.g., Page 0—Page 2) of the 9 logical bits. In one embodiment, the soft-bit read information for these bits can be determined using one of the approaches described above with respect to FIGS. 4A-4C or FIGS. 5A-5C. In In addition, a set of eight levels in Cell A expresses the next 3 logical bits (e.g., Page 3—Page 5) and a set of eight levels in Cell B expresses the final 3 logical bits (e.g., Page 6-Page 8). In one embodiment, the soft-bit read information for these logical bits can be determined in a legacy manner.

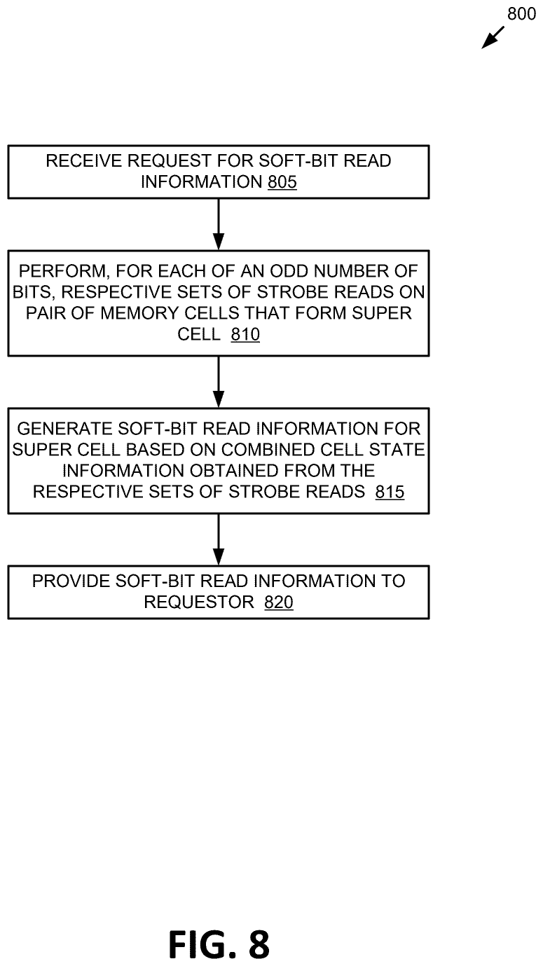

FIG. 8 is a flow diagram of an example method of performing soft-bit read operations for super cells in a memory device in accordance with some embodiments of the present disclosure. The method 800 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 800 is performed by local media controller 135 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 805, a request is received. For example, control logic (e.g., local media controller 135) can receive, from a requestor, such as a memory interface 113 of a memory sub-system controller 115, a request for soft-bit read information corresponding to at least one super cell of a memory array, such as memory array 104 of memory device 130. In one embodiment, the memory sub-system controller 115 issues the request for the soft-bit read information in response to error correction logic 113 identifying one or more errors in data previously read from memory device 130, and which were unable to be corrected using certain hardware-based error correction operations. As described above, a super cell can include a group of two or more memory cells in the memory device 130, which are associated with the same wordline, and on which an odd number of logical bits is encoded, such as one and a half (“1.5” bits per cell), and thus three (“3”) logical bits per pair of memory cells. In other embodiments, there may be three and a half (“3.5” bits per cell), and thus seven (“7”) logical bits per pair of memory cells, four and a half (“4.5” bits per cell), and thus nine (“9”) logical bits per pair of memory cells, or some other odd number of logical bits encoded.

At operation 810, a number of read operations are performed. For example, the control logic performs, for each of the odd number of data bits, respective sets of strobe reads on a pair of memory cells that form the at least one super cell. In one embodiment, the super cell, such as super cell 304, includes two memory cells (i.e., Cell A and Cell B). As described above, the super cell stores at least three data bits, which can be represented by respective cell states (i.e., Level 0, Level 1, Level 2). Depending on the coding scheme used to program the super cell, local media controller can initiate the strobe reads in order to determine the stored cell state information. Each set of strobe reads can include two or more read operations using different read voltage levels that are associated with (e.g., offset from) a default read voltage level. For example, if a given default read voltage level (e.g., R0) is positioned between two cell states (e.g., Level 0 and Level 1), the associated set of strobe reads can include one read voltage level (e.g., R0−) that is slightly lower than the default read voltage level and another read voltage level (e.g., R0+) that is slightly higher than the default read voltage level. The set of strobe reads can be performed using these offset read voltage levels in order to identify whether the memory cells in the super cell are programmed to a threshold voltage level that is near the boundary of two states, and thus is likely to be misread. Different sets of strobe reads can be performed on the pair of memory cells in order to determine cell state information associated with each of the odd number of data bits.

At operation 815, information is generated. For example, the control logic generates the soft-bit read information corresponding to the at least one super cell based on combined cell state information obtained from the respective sets of strobe reads. As described above, the soft-bit read information can indicate a likelihood of the at least one super cell being misread. As noted above, strobe reads can be performed on each individual memory cell in the pair to determine individual cell state information representing a particular data bit. The memory sub-system controller can logically combine the individual cell state information to form the combined cell state information which is representative of the soft-bit read information for that particular data bit for the super cell, as a whole. In one embodiment, logically combining the individual cell state information comprises decoding the combination of the cell state information using a predefined table, such as those illustrated above. An example, of the sets of strobe reads and generation of the corresponding soft-bit read information is described below.

In one embodiment, performing the respective sets of strobe reads on the pair of memory cells comprises performing a first set of strobe reads (e.g., R0− and R0+) associated with a first read voltage level (e.g., R0) on a first memory cell (e.g., Cell A) of the pair of memory cells, and performing a second set of strobe reads (e.g., R0− and R0+) associated with the first read voltage level (e.g., R0) on a second memory cell (e.g., Cell B) of the pair of memory cells, as illustrated in FIG. 4A. In this embodiment, generating the soft-bit read information corresponding to the at least one super cell comprises logically combining results of the first set of strobe reads and the second set of strobe reads to determine soft-bit read information for a first data bit (e.g., Page 0) stored in the at least one super cell, using the information in Table 2, for example.

In addition, performing the respective sets of strobe reads on the pair of memory cells further comprises performing a third set of strobe reads (e.g., R1− and R1+) associated with a second read voltage level (e.g., R1) on the first memory cell (e.g., Cell A) of the pair of memory cells, and performing a fourth set of strobe reads (e.g., R1− and R1+) associated with the second read voltage level (e.g., R1) on the second memory cell (e.g., Cell B) of the pair of memory cells, as illustrated in FIG. 4B. In this embodiment, generating the soft-bit read information corresponding to the at least one super cell comprises logically combining results of the third set of strobe reads and the fourth set of strobe reads to determine soft-bit read information for a second data bit (e.g., Page 1) stored in the at least one super cell, using the information in Table 3, for example.

Furthermore, performing the respective sets of strobe reads on the pair of memory cells further comprises performing a fifth set of strobe reads (e.g., R0−, R0+, R1−, and R1+) associated with the first read voltage level (e.g., R0) and the second read voltage level (e.g., R1) on the first memory cell (e.g., Cell A) of the pair of memory cells, performing a sixth set of strobe reads (e.g., R0−, R0+, R1−, and R1+) associated with the first read voltage level (e.g., R0) and the second read voltage level (e.g., R1) on the second memory cell (e.g., Cell B) of the pair of memory cells, as illustrated in FIG. 4C. The operations further include performing a seventh set of strobe reads using a high strobe voltage level (e.g., R0+) associated with the first read voltage level and a low strobe voltage level (e.g., R1−) associated with the second read voltage level on the first memory cell (e.g., Cell A) of the pair of memory cells, and performing an eighth set of strobe reads using the high strobe voltage level (e.g., R0+) associated with the first read voltage level and the low strobe voltage level (e.g., R1−) associated with the second read voltage level on the second memory cell (e.g., Cell B) of the pair of memory cells, as illustrated in FIG. 4C. In this embodiment, generating the soft-bit read information corresponding to the at least one super cell comprises logically combining results (e.g., SB[0]) of the fifth set of strobe reads and the sixth set of strobe reads to determine initial soft-bit read information for a third data bit (e.g., Page 2) stored in the at least one super cell and modifying the initial soft-bit read information based on results (e.g., SB[1]) of the seventh set of strobe reads and the eighth set of strobe reads to determine final soft-bit read information for the third data bit (e.g., Page 2) stored in the at least one super cell, using the information in Table 4 and Table 5, respectively, for example.

At operation 820, information is provided. For example, the control logic can provide, to the requestor, the soft-bit read information corresponding to the at least one super cell. In one embodiment, the memory sub-system controller 135 provides the soft-bit read information for each of the three bits stored in the super cell to memory interface 113 of memory sub-system controller 115. Upon receipt, error correction logic 113 can perform one or more soft error correction operations on the data read from memory device 130 using the soft-bit read information to correct any errors in the data. For example, error correction logic 113 can select specific soft error correction operations and/or focus error correction on those certain super cells identified as more likely to be misread in order to improve the efficiency of the soft error correction operations.

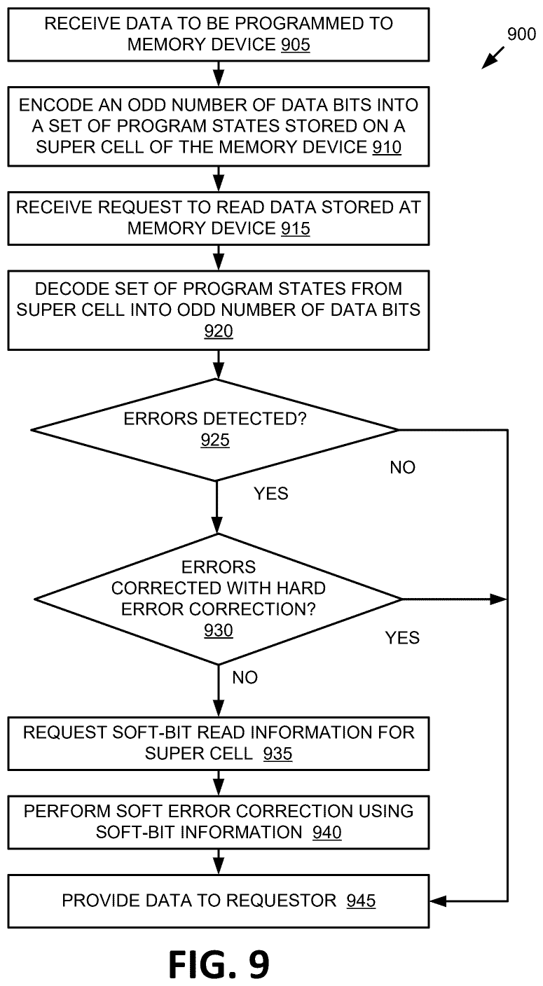

FIG. 9 is a flow diagram of an example method of performing error correction operations for super cells in a memory device using soft-bit read information in accordance with some embodiments of the present disclosure. The method 900 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 900 is performed by memory sub-system controller 115 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 905, data is received. For example, processing logic (e.g., error correction logic 113 of memory sub-system controller 115) can receive data to be programmed to a memory device, such as memory device 130 of memory sub-system 110.

At operation 910, data is encoded. For example, the processing logic can encode an odd number of data bits (e.g., three bits, seven bits, nine bits) into a set of program states stored on a super cell, such as super cell 304, of the memory device 130. In one embodiment, the data bits are encoded by encoder 182 of error correction logic 113.

At operation 920, a request is received. For example, the processing logic can receive a request to read data stored in the super cell 304 of the memory deice 130.

At operation 925, data is decoded. For example, the processing logic can receive the data from the memory device 130 and can decode the set of program states from the super cells into the odd number of data bits. In one embodiment, the program states are decoded by decoder 184 of error correction logic 113.

At operation errors are detected. For example, the processing logic can detect one or more errors in the data read from the memory device 130. If no errors are detected, the processing logic can provide the data to the requestor at operation 945.

If one or more errors are detected, however, at operation 930, the processing logic determines whether the error can be corrected using hardware-based error correction operations. If the errors are corrected using the hardware-based error correction operations, the processing logic can provide the data to the requestor at operation 945.

If the errors cannot be corrected using the hardware-based error correction operations, however, at operation 935, soft-bit read information is requested. For example, the processing logic can request soft-bit read information corresponding to the super cell from the memory device 130. In one embodiment, the soft-bit read information is based on combined cell state information obtained from respective sets of strobe reads performed on a pair of memory cells that form the super cell and indicates a likelihood of the super cell being misread.

At operation 940, the soft-bit read information is received. For example, the processing logic can receive the soft-bit read information from the memory device 130 and can perform one or more soft error correction operations on the odd number of data bits read from the memory device 130 and decoded by the decoder 184 using the soft-bit read information. For example, error correction logic 113 can select specific soft error correction operations and/or focus error correction on those certain super cells identified as more likely to be misread in order to improve the efficiency of the soft error correction operations.

At operation 945, data is provided to the requestor. For example, the processing logic can provide the data, as corrected by the soft error correction operations, to the requestor, such as host system 120.

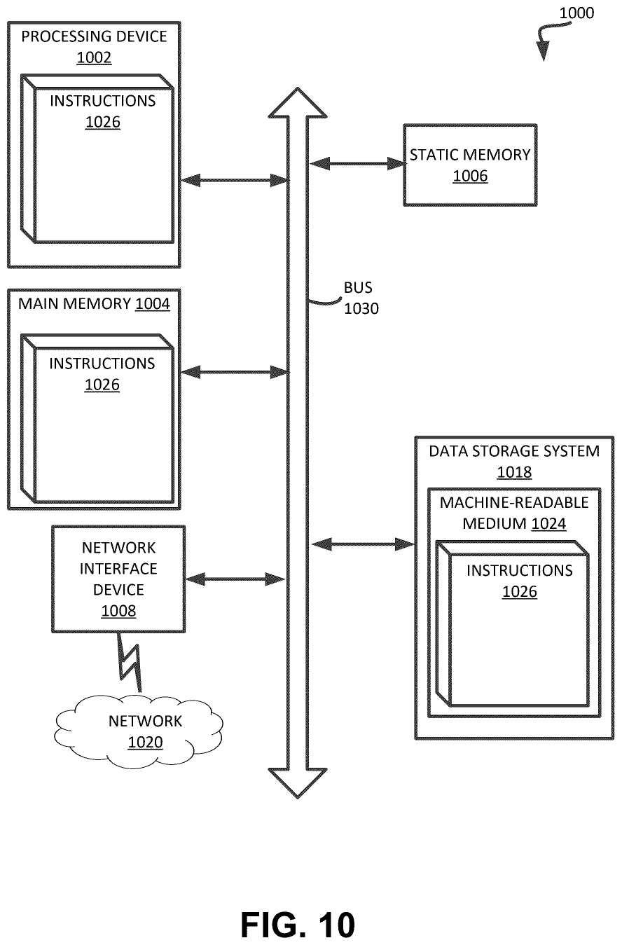

FIG. 10 illustrates an example machine of a computer system 1000 within which a set of instructions, for causing the machine to perform any one or more of the methodologies discussed herein, can be executed. In some embodiments, the computer system 1000 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the error correction logic 113 or local media controller 135 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1000 includes a processing device 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), etc.), and a data storage system 1018, which communicate with each other via a bus 1030.

Processing device 1002 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1002 can also be one or more special-purpose processing devices such as an application specific integrated circuit (ASIC), a field programmable gate array (FPGA), a digital signal processor (DSP), network processor, or the like. The processing device 1002 is configured to execute instructions 1026 for performing the operations and steps discussed herein. The computer system 1000 can further include a network interface device 1008 to communicate over the network 1020.

The data storage system 1018 can include a machine-readable storage medium 1024 (also known as a computer-readable medium) on which is stored one or more sets of instructions 1026 or software embodying any one or more of the methodologies or functions described herein. The instructions 1026 can also reside, completely or at least partially, within the main memory 1004 and/or within the processing device 1002 during execution thereof by the computer system 1000, the main memory 1004 and the processing device 1002 also constituting machine-readable storage media. The machine-readable storage medium 1024, data storage system 1018, and/or main memory 1004 can correspond to the memory sub-system 110 of FIG. 1.

In one embodiment, the instructions 1026 include instructions to implement functionality corresponding to the error correction logic 113 of FIG. 1. While the machine-readable storage medium 1024 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a plurality of memory cells, wherein respective pairs of the memory cells are grouped into super cells to store an odd number of data bits; and
control logic, operatively coupled with the memory array, to perform operations comprising:
receiving, from a requestor, a request for soft-bit read information corresponding to at least one super cell of the memory array;
performing, for each of the odd number of data bits, respective sets of strobe reads on a pair of memory cells that form the at least one super cell;
generating the soft-bit read information corresponding to the at least one super cell based on combined cell state information obtained from the respective sets of strobe reads, the soft-bit read information to indicate a likelihood of the at least one super cell being misread; and
providing, to the requestor, the soft-bit read information corresponding to the at least one super cell.

2. The memory device of claim 1, wherein performing the respective sets of strobe reads on the pair of memory cells comprises:
performing a first set of strobe reads associated with a first read voltage level on a first memory cell of the pair of memory cells; and
performing a second set of strobe reads associated with the first read voltage level on a second memory cell of the pair of memory cells.

3. The memory device of claim 2, wherein generating the soft-bit read information corresponding to the at least one super cell comprises:
logically combining results of the first set of strobe reads and the second set of strobe reads to determine soft-bit read information for a first data bit stored in the at least one super cell.

4. The memory device of claim 3, wherein performing the respective sets of strobe reads on the pair of memory cells further comprises:
performing a third set of strobe reads associated with a second read voltage level on the first memory cell of the pair of memory cells; and
performing a fourth set of strobe reads associated with the second read voltage level on the second memory cell of the pair of memory cells.

5. The memory device of claim 4, wherein generating the soft-bit read information corresponding to the at least one super cell comprises:
logically combining results of the third set of strobe reads and the fourth set of strobe reads to determine soft-bit read information for a second data bit stored in the at least one super cell.

6. The memory device of claim 5, wherein performing the respective sets of strobe reads on the pair of memory cells further comprises:
performing a fifth set of strobe reads associated with the first read voltage level and the second read voltage level on the first memory cell of the pair of memory cells;
performing a sixth set of strobe reads associated with the first read voltage level and the second read voltage level on the second memory cell of the pair of memory cells;
performing a seventh set of strobe reads using a high strobe voltage level associated with the first read voltage level and a low strobe voltage level associated with the second read voltage level on the first memory cell of the pair of memory cells; and
performing an eighth set of strobe reads using the high strobe voltage level associated with the first read voltage level and the low strobe voltage level associated with the second read voltage level on the second memory cell of the pair of memory cells.

7. The memory device of claim 6, wherein generating the soft-bit read information corresponding to the at least one super cell comprises:
logically combining results of the fifth set of strobe reads and the sixth set of strobe reads to determine initial soft-bit read information for a third data bit stored in the at least one super cell; and
modifying the initial soft-bit read information based on results of the seventh set of strobe reads and the eighth set of strobe reads to determine final soft-bit read information for the third data bit stored in the at least one super cell.

8. A method comprising:
receiving, from a requestor, a request for soft-bit read information corresponding to at least one super cell of a memory array of a memory device, the memory array comprising a plurality of memory cells, wherein respective pairs of the memory cells are grouped into super cells to store an odd number of data bits;
performing, for each of the odd number of data bits, respective sets of strobe reads on a pair of memory cells that form the at least one super cell;
generating the soft-bit read information corresponding to the at least one super cell based on combined cell state information obtained from the respective sets of strobe reads, the soft-bit read information to indicate a likelihood of the at least one super cell being misread; and
providing, to the requestor, the soft-bit read information corresponding to the at least one super cell.

9. The method of claim 8, wherein performing the respective sets of strobe reads on the pair of memory cells comprises:
performing a first set of strobe reads associated with a first read voltage level on a first memory cell of the pair of memory cells; and
performing a second set of strobe reads associated with the first read voltage level on a second memory cell of the pair of memory cells.

10. The method of claim 9, wherein generating the soft-bit read information corresponding to the at least one super cell comprises:
logically combining results of the first set of strobe reads and the second set of strobe reads to determine soft-bit read information for a first data bit stored in the at least one super cell.

11. The method of claim 10, wherein performing the respective sets of strobe reads on the pair of memory cells further comprises:
performing a third set of strobe reads associated with a second read voltage level on the first memory cell of the pair of memory cells; and
performing a fourth set of strobe reads associated with the second read voltage level on the second memory cell of the pair of memory cells.

12. The method of claim 11, wherein generating the soft-bit read information corresponding to the at least one super cell comprises:
logically combining results of the third set of strobe reads and the fourth set of strobe reads to determine soft-bit read information for a second data bit stored in the at least one super cell.

13. The method of claim 12, wherein performing the respective sets of strobe reads on the pair of memory cells further comprises:
performing a fifth set of strobe reads associated with the first read voltage level and the second read voltage level on the first memory cell of the pair of memory cells;
performing a sixth set of strobe reads associated with the first read voltage level and the second read voltage level on the second memory cell of the pair of memory cells;
performing a seventh set of strobe reads using a high strobe voltage level associated with the first read voltage level and a low strobe voltage level associated with the second read voltage level on the first memory cell of the pair of memory cells; and
performing an eighth set of strobe reads using the high strobe voltage level associated with the first read voltage level and the low strobe voltage level associated with the second read voltage level on the second memory cell of the pair of memory cells.

14. The method of claim 13, wherein generating the soft-bit read information corresponding to the at least one super cell comprises:
logically combining results of the fifth set of strobe reads and the sixth set of strobe reads to determine initial soft-bit read information for a third data bit stored in the at least one super cell; and
modifying the initial soft-bit read information based on results of the seventh set of strobe reads and the eighth set of strobe reads to determine final soft-bit read information for the third data bit stored in the at least one super cell.

15. A system comprising:
a memory device comprising a memory array comprising a plurality of memory cells, wherein a pair of the memory cells are grouped into a super cell to store an odd number of data bits; and
a processing device, operatively coupled with the memory device, the processing device to request soft-bit read information corresponding to the super cell from the memory device, wherein the soft-bit read information is based on combined cell state information obtained from respective sets of strobe reads performed on the pair of memory cells and indicates a likelihood of the super cell being misread.

16. The system of claim 15, further comprising:
an encoder configured to encode the odd number of data bits into a set of program states stored on a super cell of the memory array; and
a decoder configured to decode the set of program states from the super cells into the odd number of data bits.

17. The system of claim 16, wherein the processing device is to request the soft-bit read information corresponding to the super cell from the memory device in response to one or more hard error correction operations performed on the odd number of data bits read from the memory device and decoded by the decoder failing.

18. The system of claim 16, wherein the processing device is further to perform one or more soft error correction operations on the odd number of data bits read from the memory device and decoded by the decoder using the soft-bit read information.

19. The system of claim 15, wherein the combined cell state information is obtained from respective sets of strobe reads performed on the pair of memory cells for each of the odd number of data bits.

20. The system of claim 15, wherein the odd number of data bits stored in the pair of memory cells of the super cell comprises at least one of three data bits, seven data bits, or nine data bits.
